(19) United States
(12) Patent Application Publication
(10) Pub. No.: US 2024/0206179 A1
(43) Pub. Date: Jun. 20, 2024

(54) THREE-DIMENSIONAL MEMORY DEVICES AND METHODS FOR FORMING THE SAME

(71) Applicant: YANGTZE MEMORY TECHNOLOGIES CO., LTD., Wuhan (CN)

(72) Inventors: Mingkang Zhang, Wuhan (CN); Yingcheng Zhao, Wuhan (CN); Liang Xiao, Wuhan (CN); Yihuan Wang, Wuhan (CN)

(21) Appl. No.: 18/223,448

(22) Filed: Jul. 18, 2023

Related U.S. Application Data
(60) Provisional application No. 63/433,120, filed on Dec. 16, 2022.

(30) Foreign Application Priority Data
Jul. 11, 2023 (CN) 202310847908.5

(51) Int. Cl. H10B 43/35; H01L 23/528; H10B 41/10; H10B 41/27; H10B 41/35; H10B 43/10; H10B 43/27

(52) U.S. Cl. CPC H10B 43/35; H01L 23/5283; H10B 41/10; H10B 41/27; H10B 41/35; H10B 43/10; H10B 43/27

(57) ABSTRACT

A three-dimensional (3D) memory device and methods for forming the same are provided. The 3D memory device includes a first semiconductor structure having a core region and a non-array region. The first semiconductor structure includes: an array of channel structures in the core region; a substrate layer extending from the non-array region to the core region and being in contact with the array of channel structures; an insulating structure including a first portion extending along a lateral direction from the non-array region to the core region and a second portion extending along a vertical direction through the substrate layer in the non-array region, where the second portion of the insulating structure surrounds the core region; and contact structures penetrating through the second portion of the insulating structure, where the contact structures are electrically insulated from the substrate layer by the insulating structure.

### CROSS-REFERENCE TO RELATED APPLICATIONS

This application claims the benefit of priorities to C.N. Application No. 202310847908.5, filed on Jul. 11, 2023, and U.S. Provisional Application No. 63/433,120, filed on Dec. 16, 2022, which are hereby incorporated by reference in their entirety.

### BACKGROUND

The present disclosure relates to memory devices and fabrication methods thereof.

Planar memory cells are scaled to smaller sizes by improving process technology, circuit design, programming algorithm, and fabrication process. However, as feature sizes of the memory cells approach a lower limit, the planar process and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

In one aspect, a 3D memory device is disclosed. The 3D memory device includes a first semiconductor structure having a core region and a non-array region. The first semiconductor structure includes: an array of channel structures in the core region; a substrate layer extending from the non-array region to the core region and being in contact with the array of channel structures; an insulating structure including a first portion extending along a lateral direction from the non-array region to the core region and a second portion extending along a vertical direction through the substrate layer in the non-array region, where the second portion of the insulating structure surrounds the core region; and contact structures penetrating through the second portion of the insulating structure, where the contact structures are electrically insulated from the substrate layer by the insulating structure.

In another aspect, a system including a memory device and a memory controller is disclosed. The memory device is configured to store data and includes a first semiconductor structure having a core region and a non-array region. The first semiconductor structure includes: an array of channel structures in the core region; a substrate layer extending from the non-array region to the core region and being in contact with the array of channel structures; an insulating structure including a first portion extending along a lateral direction from the non-array region to the core region and a second portion extending along a vertical direction through the substrate layer in the non-array region, where the second portion of the insulating structure surrounds the core region; and contact structures penetrating through the second portion of the insulating structure. The contact structures are electrically insulated from the substrate layer by the insulating structure, and a minimum lateral width of the contact structures is less than a minimum lateral distance between the contact structures and the substrate layer. The memory device further includes a second semiconductor structure bonded with the first semiconductor structure. The second semiconductor structure includes a transistor. The memory controller is coupled to the memory device and configured to control the memory device.

In yet another aspect, a method for forming a 3D memory device is disclosed. The method includes: forming a first semiconductor structure including a core region and a non-array region; depositing a photoresist layer over the core region and the non-array region of the first semiconductor structure; patterning the photoresist layer to expose a substrate layer in the non-array region; removing a first portion of the substrate layer to form a first opening, where the first opening exposes a plurality of first contact portions and surrounds the core region; forming an insulating structure filling the first opening; removing a plurality of portions of the insulating structure to form a plurality of second openings, each second opening exposing a corresponding first contact portion; and forming a plurality of second contact portions in the plurality of second openings, each second contact portion being in contact with the corresponding first contact portion, where the plurality of first contact portions and the plurality of second contact portions together form a plurality of first contact structures.

### BRIEF DESCRIPTION OF DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1A illustrates a schematic view of a cross-section of a 3D memory device, according to some aspects of the present disclosure.

FIG. 1B illustrates an overview of the 3D memory device, according to some aspects of the present disclosure.

FIG. 2 illustrates a cross-sectional view of an exemplary 3D memory device shown in FIGS. 1A and 1B, according to some aspects of the present disclosure.

FIGS. 3A-3F illustrate a fabrication process for forming the 3D memory devices in FIG. 2, according to some aspects of the present disclosure.

FIG. 4A and FIG. 4B illustrate a plan view for forming the 3D memory devices in FIG. 2, according to some aspects of the present disclosure.

FIG. 5 illustrates a flowchart of a method for forming the 3D memory devices in FIG. 2, according to some aspects of the present disclosure.

FIG. 6 illustrates a block diagram of an exemplary system having a memory device, according to some aspects of the present disclosure.

FIG. 7A illustrates a diagram of an exemplary memory card having a memory device, according to some aspects of the present disclosure.

FIG. 7B illustrates a diagram of an exemplary solid-state drive (SSD) having a memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures, or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

In 3D memory devices, peripheral circuits and memory cell arrays of a memory device are disposed in different planes (levels, tiers) in the vertical direction, e.g., stacked over one another, to reduce the planar chip size of the peripheral circuits, as well as the total chip size of the memory device. In 3D memory devices, the memory cells are formed by the intersections of NAND memory channels and word lines. The NAND memory channels are formed extending vertically in the memory stack (e.g., conductive/dielectric layer pairs), and the source ends of the NAND memory channels are in contact with a semiconductor layer that functions as part of a source contact for applying a source voltage on the NAND memory channels. The memory stacks and the peripheral circuits are often integrated together through bonding in the 3D NAND Flash memory devices.

To form electrical connections in a 3D memory device (e.g., between the memory cell arrays and the peripheral circuits) and/or beyond the 3D memory device (e.g., between the 3D NAND Flash memory device and external circuitry), through-silicon contacts (TSCs) are often formed. To insulate the TSCs from the semiconductor layer, the portion of the semiconductor layer in contact with the NAND memory channels is often disconnected from the portion of the semiconductor layer through which the TSCs extend. An insulating portion is formed between the two portions of the semiconductor layer for insulation. Meanwhile, a respective insulating spacer is formed in the semiconductor layer such that the TSCs is each insulated from the semiconductor layer by the respective insulating spacer. The insulating spacers and the insulating portion are often formed by patterning the semiconductor layer to form openings and filling the openings with a dielectric material. Due to the small critical dimensions of these openings, the deposition of the dielectric material often includes atomic layer deposition (ALD). This fabrication process can be costly due to the high expense of photolithography, etching, and deposition. Meanwhile, the small critical dimensions of the openings can cause the etching process to form the openings to be undesirably complex, and the precise alignment between the openings and the TSCs to be challenging.

To address one or more of the aforementioned issues, the present disclosure provides structures and fabrication methods of a 3D memory device, in which the critical dimension of the opening to form the insulating layer that insulates the TSCs and the semiconductor layer is increased, and the etching process to form the opening is less challenging. The cost and the difficulty in insulating different portions of a semiconductor layer can be reduced. The 3D memory device, having a core region and a non-array region, includes a plurality of NAND memory channels in the core region and one or more TSCs in the non-array region. A semiconductor layer is in contact with the source ends of the NAND channels in the core region. According to the present disclosure, instead of forming a respective insulating spacer to insulate each TSC from the semiconductor layer, a single insulating layer can be formed to insulate a plurality of TSCs from the semiconductor layer. A lateral width of the insulating layer is sufficiently large to insulate any (e.g., all) TSCs from the semiconductor layer. The insulating layer can be formed at any suitable location where insulation is needed and is away from the source ends of the NAND memory channels. For example, the insulating layer can be formed in the non-array region. The insulating layer is in contact with the semiconductor layer laterally. In some implementations, the insulating layer includes a dielectric material such as one or more of silicon oxide, silicon nitride, or silicon oxynitride. In some implementations, the material in the non-array region that is not used for conducting electricity may be etched off, followed by depositing an insulating layer, hence reducing parasitic capacity and improving device performance.

In the fabrication process of the present disclosure, a lithography process is first conducted for the formation of a first opening in which the insulating layer is formed. The critical dimension of the first opening is desirably large. The larger critical dimension of the insulating layer allows deposition methods, such as chemical vapor deposition (CVD) and/or physical vapor deposition (PVD), other than atomic layer deposition (ALD), to be used for forming the insulating layer, thus reducing the fabrication cost. The increased area of the insulating layer can also reduce the parasitic capacity of the 3D memory device.

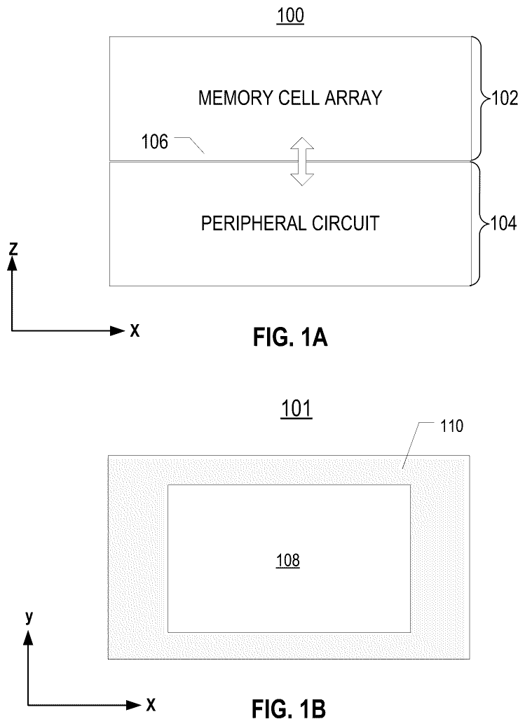

FIG. 1A illustrates a schematic view of a cross-section of a 3D memory device 100, according to some aspects of the present disclosure. FIG. 1B illustrates an overview of 3D memory device 101, according to some aspects of the present disclosure. 3D memory device 100 represents an example of a bonded chip. In some implementations, at least some of the components of 3D memory device 100 (e.g., memory cell array and peripheral circuits) are formed separately on different substrates in parallel and then jointed to form a bonded chip (a process referred to herein as a “parallel process”).

It is noted that x-, y-, and z- axes are added in the figures of the present disclosure to further illustrate the spatial relationships of the components of a semiconductor device. A substrate of a semiconductor device, e.g., 3D memory device 100, includes two lateral surfaces (e.g., a top surface and a bottom surface) extending laterally in the x-direction and y-direction (the lateral directions or width directions). The x-direction is the word line direction of 3D memory device 100, the y-direction is the bit line direction of 3D memory device 100, and the z-direction is perpendicular to the x-y plane. In some implementations, the z-direction is the NAND direction in which the NAND memory channels extend vertically. As used herein, whether one component (e.g., a layer or a device) is “on,” “above,” or “below” another component (e.g., a layer or a device) of a semiconductor device is determined relative to the substrate of the semiconductor device in the z-direction (the vertical direction or thickness direction) when the substrate is positioned in the lowest plane of the semiconductor device in the z-direction. The same notion for describing the spatial relationships is applied throughout the present disclosure.

3D memory device 100 can include a first semiconductor structure 102 including an array of memory cells (also referred to herein as a “memory cell array”). In some implementations, the memory cell array includes an array of NAND Flash memory cells. For ease of description, a NAND Flash memory cell array may be used as an example for describing the memory cell array in the present disclosure. But it is understood that the memory cell array is not limited to NAND Flash memory cell array and may include any other suitable types of memory cell arrays, such as NOR Flash memory cell array, phase change memory (PCM) cell array, resistive memory cell array, magnetic memory cell array, spin transfer torque (STT) memory cell array, to name a few.

First semiconductor structure 102 can be a NAND Flash memory device in which memory cells are provided in the form of an array of 3D NAND memory channels and/or an array of two-dimensional (2D) NAND memory cells. NAND memory cells can be organized into pages or fingers, which are then organized into blocks in which each NAND memory cell is coupled to a separate line called a bit line (BL). All cells with the same vertical position in the NAND memory cell can be coupled through the control gates by a word line (WL). In some implementations, a memory plane contains a certain number of blocks that are coupled through the same bit line. First semiconductor structure 102 can include one or more memory planes, and the peripheral circuits that are needed to perform all the read/program (write)/erase operations can be included in a second semiconductor structure 104.

In some implementations, the array of NAND memory cells is an array of 2D NAND memory cells, each of which includes a floating-gate transistor. The array of 2D NAND memory cells includes a plurality of 2D NAND memory channels, each of which includes a plurality of memory cells connected in series (resembling a NAND gate) and two select transistors, according to some implementations. Each 2D NAND memory channel is arranged in the same plane (i.e., referring to herein a flat, two-dimensional (2D) surface, different from the term “memory plane” in the present discourse) on the substrate, according to some implementations. In some implementations, the array of NAND memory cells is an array of 3D NAND memory channels, each of which extends vertically above a semiconductor layer (in 3D) through a stack structure, e.g., a memory stack. Depending on the 3D NAND technology (e.g., the number of layers/tiers in the memory stack), a 3D NAND memory channel typically includes a certain number of NAND memory cells, each of which includes a floating-gate transistor or a charge-trap transistor.

As shown in FIG. 1A, 3D memory device 100 can also include a second semiconductor structure 104 having the peripheral circuits of the memory cell array in first semiconductor structure 102. The peripheral circuits (a.k.a. control and sensing circuits) can include any suitable digital, analog, and/or mixed-signal circuits used for facilitating the operations of the memory cell array. For example, the peripheral circuits can include one or more of a page buffer, a decoder (e.g., a row decoder and a column decoder), a sense amplifier, a driver (e.g., a word line driver), an I/O circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits in second semiconductor structure 104 can use complementary metal-oxide-semiconductor (CMOS) technology, e.g., which can be implemented with logic processes in any suitable technology nodes.

As shown in FIG. 1A, first semiconductor structure 102 and second semiconductor structure 104 are stacked over one another in different planes, according to some implementations. As a result, the memory cell array in first semiconductor structure 102 and the peripheral circuits in second semiconductor structure 104 can be stacked over one another in different planes to reduce the planar size of 3D memory device 100, compared with memory devices in which all the peripheral circuits are disposed in the same plane. As shown in FIG. 1A, in some implementations, first semiconductor structure 102 is above second semiconductor structure 104 and includes a pad-out interconnect layer for pad-out purposes. TSVs may be formed extending in first semiconductor structure 102, providing electrical connection between components in 3D memory device 100 (e.g., the peripheral circuits and/or the memory cell array) and any external circuitry.

As shown in FIG. 1A, 3D memory device 100 further includes a bonding interface 106 vertically between first semiconductor structure 102 and second semiconductor structure 104. Bonding interface 106 can be an interface between two semiconductor structures formed by any suitable bonding technologies described below in detail, such as hybrid bonding, anodic bonding, fusion bonding, transfer bonding, adhesive bonding, eutectic bonding, to name a few. Data transfer between the memory cell array in first semiconductor structure 102 and the peripheral circuit in second semiconductor structure 104 can be performed through the interconnects (e.g., bonding contacts) across bonding interface 106. As shown in FIG. 1A, in some implementations, in the z-direction, the memory cell array is above bonding interface 106, and the peripheral circuit is below bonding interface 106.

As described below in detail, some of first and second semiconductor structures 102 and 104 can be fabricated separately (and in parallel in some implementations) by the parallel process, such that the thermal budget of fabricating one of first and second semiconductor structures 102 and 104 does not limit the processes of fabricating another one of first and second semiconductor structures 102 and 104. Moreover, a large number of interconnects (e.g., bonding contacts and/or inter-layer vias (ILVs)/through substrate vias (TSVs)) can be formed across bonding interface 106 to make direct, short-distance (e.g., micron- or submicron-level) electrical connections between adjacent semiconductor structures 102 and 104.

FIG. 1B illustrates an overview of 3D memory device 101, according to some aspects of the present disclosure. FIG. 1B shows a core region 108 and a non-array region 110 in first semiconductor structure 102, in the x-y plane. In some implementations, the memory cell array is formed in core region 108, and the TSCs are formed in non-array region 110. In some implementations, non-array region 110 is located in the outer periphery of core region 108 or surrounds core region 108. For example, non-array region 110 may be a region away from the memory cell arrays, e.g., a staircase region. In various implementations, other periphery regions may be included in non-array region 110 but are not part of the staircase region. In some implementations, in the x-y plane, non-array region 110 and core region 108 do not overlap with each other.

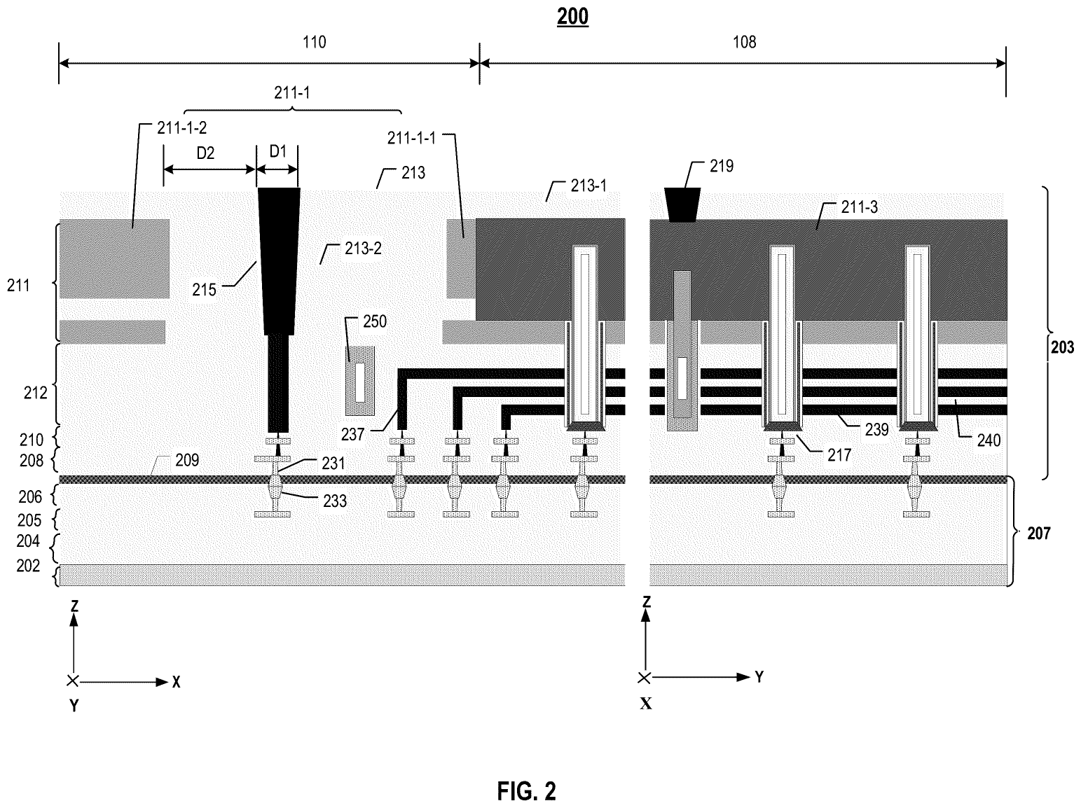

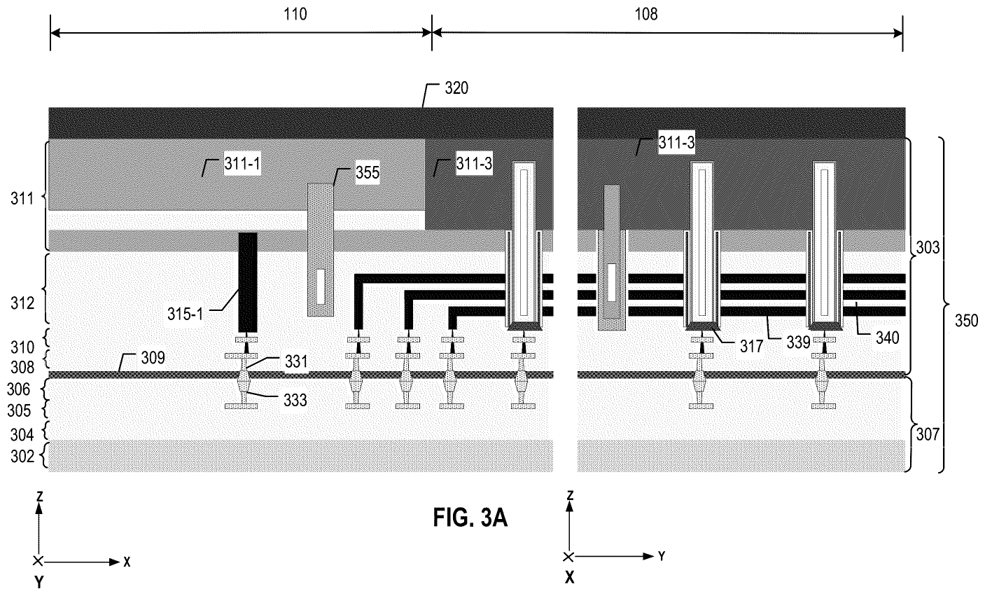

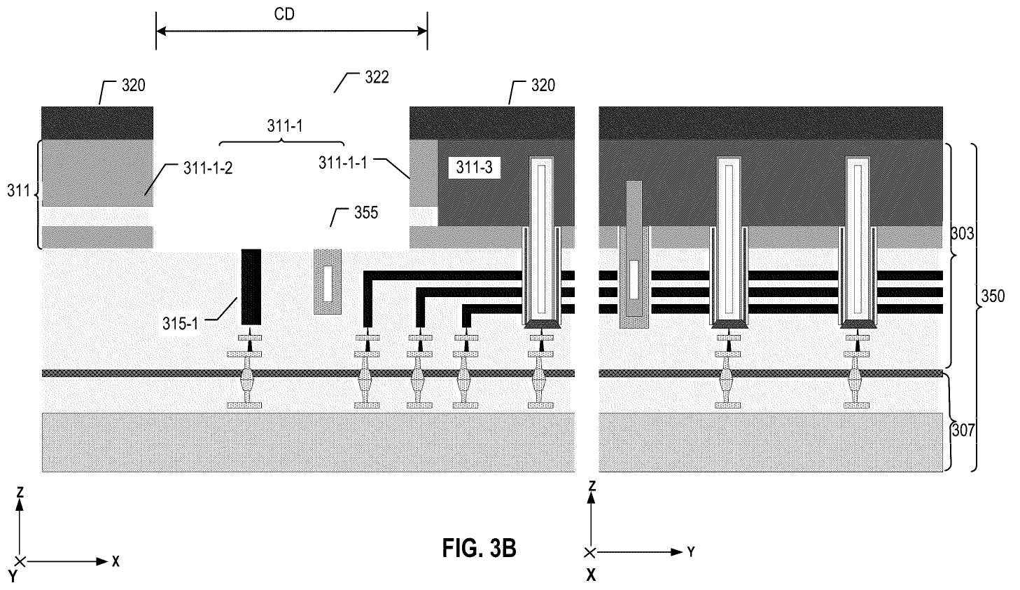

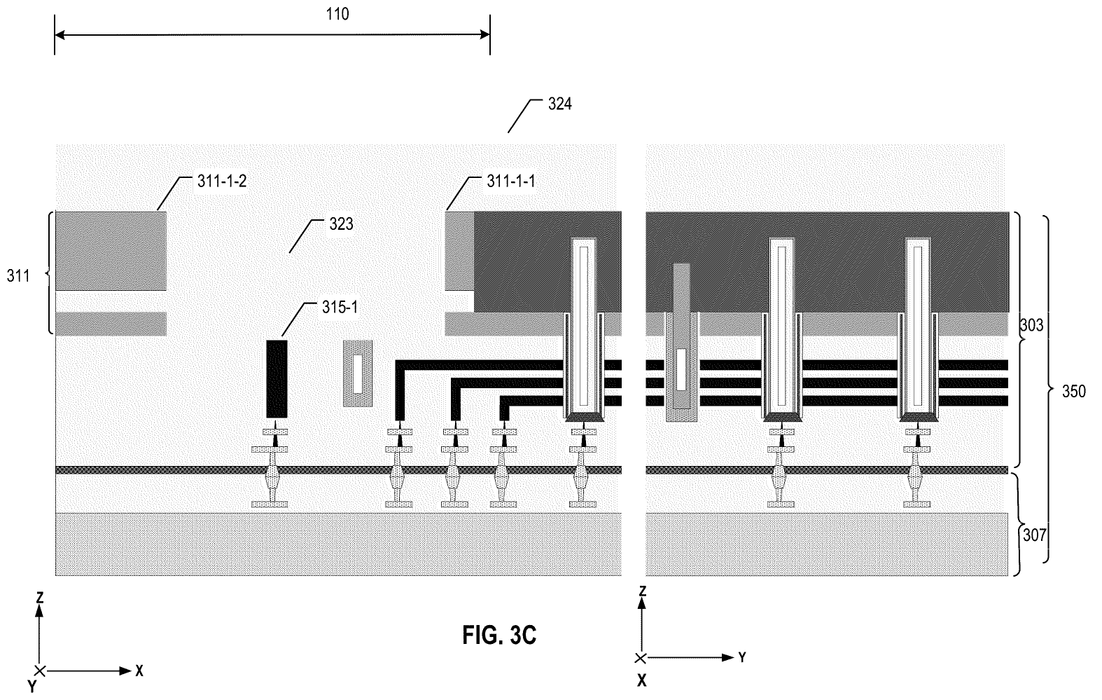

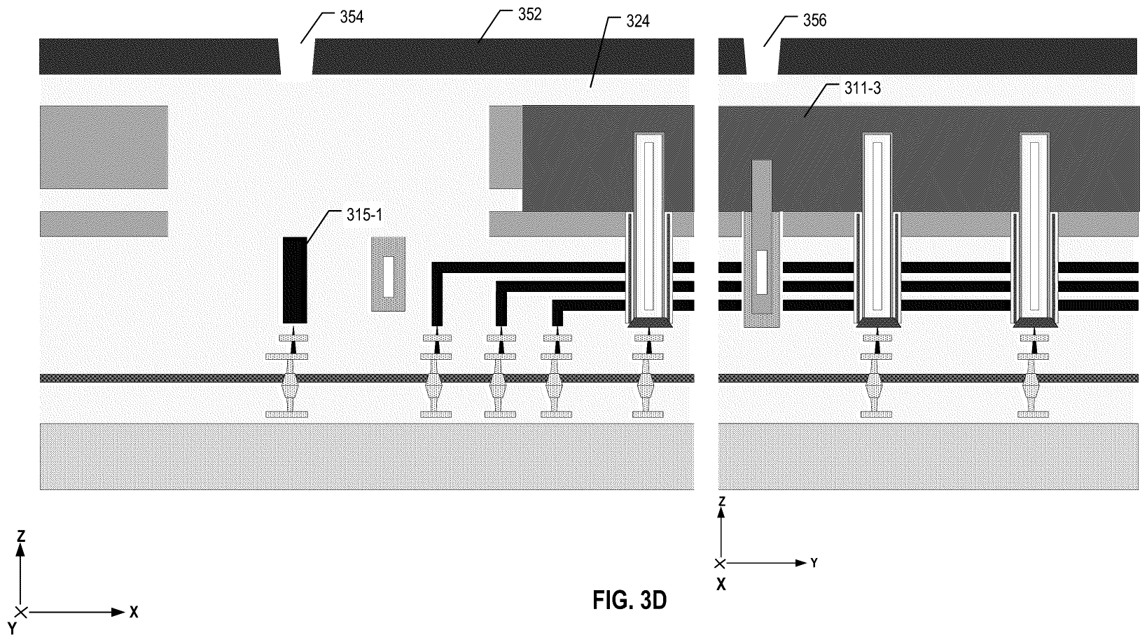

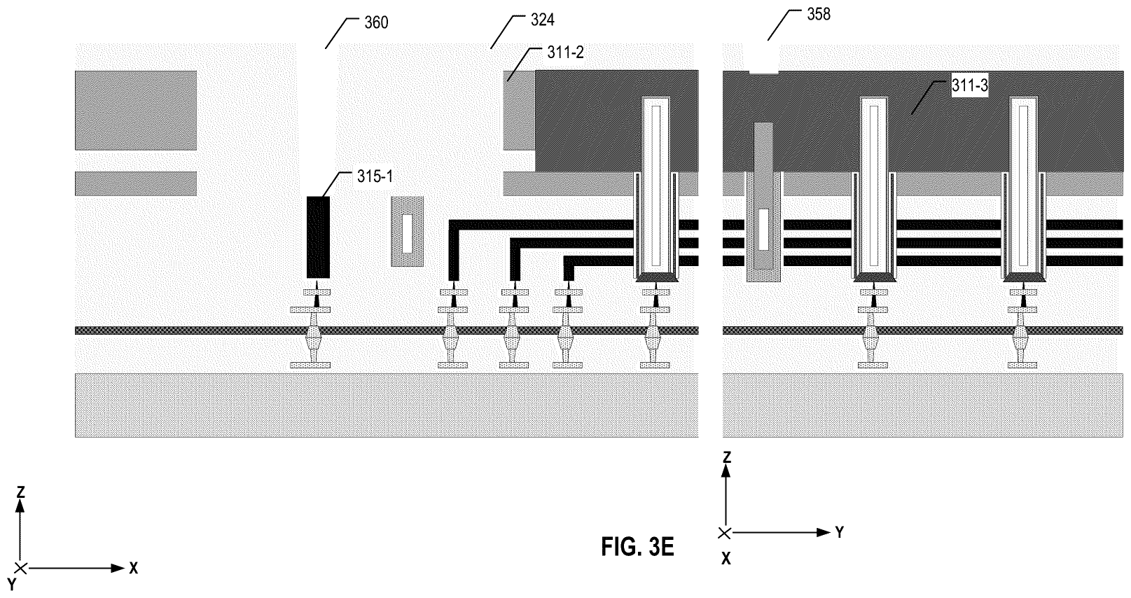

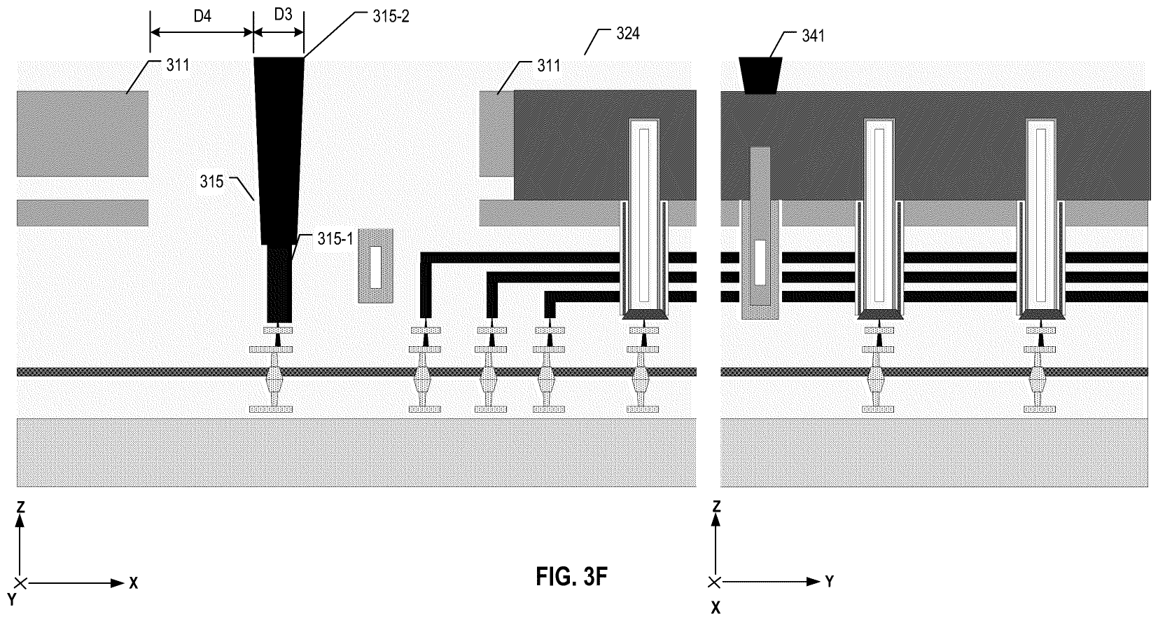

FIG. 2 illustrates a cross-sectional view of part of an exemplary 3D memory device 200, according to some aspects of the present disclosure. 3D memory device 200 can be an example of 3D memory device 100 and is a bonded chip including first semiconductor structure 203 and second semiconductor structure 207, stacked in different planes in the vertical direction (e.g., the z-direction), according to some implementations. First and second semiconductor structures 203 and 207 are bonded at bonding interface 209 therebetween, according to some implementations. It should be noted that, the components shown in FIG. 2 and FIGS. 3A-3F are meant for showing the relative positions and do not indicate the actual electrical connections in 3D memory device 200.

As shown in FIG. 2, first and second semiconductor structures 203 and 207 may be bonded to each other in a face-to-face manner at bonding interface 209. Second semiconductor structure 207 can include a substrate 202 and a device layer 204 above and in contact with substrate 202. Substrate 202 can include silicon (e.g., single crystalline silicon), silicon germanium (SiGe), gallium arsenide (GaAs), germanium (Ge), silicon on insulator (SOI), germanium on insulator (GOI), or any other suitable semiconductor materials. In some implementations, device layer 204 includes a peripheral circuit (details not shown in the figures). The peripheral circuit can include high voltage (HV) circuits, such as driving circuits, and low voltage (LV) circuits, such as page buffer circuits and logic circuits. In some implementations, the peripheral circuit includes a plurality of transistors in contact with substrate 202. The transistors can include any transistors disclosed herein, such as planar transistors and 3D transistors.

In some implementations, second semiconductor structure 207 further includes a first interconnect layer 205 above device layer 204 to transfer electrical signals to and from the peripheral circuit in device layer 204. As shown in FIG. 2, first interconnect layer 205 can be vertically between bonding interface 209 and device layer 204 (including the transistors of the peripheral circuit). First interconnect layer 205 can include a plurality of interconnects, including lateral lines and vias. As used herein, the term “interconnects” can broadly include any suitable types of interconnects, such as middle-end-of-line (MEOL) interconnects and back-end-of-line (BEOL) interconnects. Interconnects can be coupled to the transistors of the peripheral circuit in device layer 204. First interconnect layer 205 can further include one or more interlayer dielectric (ILD) layers (also known as “intermetal dielectric (IMD) layers”) in which the lateral lines and vias can form. That is, first interconnect layer 205 can include lateral lines and vias in multiple ILD layers. In some implementations, the devices in device layer 204 are coupled to one another through the interconnects in first interconnect layer 205. The interconnects in first interconnect layer 205 can include conductive materials including, but not limited to, W, Co, Cu, Al, silicides, or any combination thereof. The ILD layers in first interconnect layer 205 can include dielectric materials including, but not limited to, silicon oxide, silicon nitride, silicon oxynitride, low dielectric constant (low-k) dielectrics, or any combination thereof. In some implementations, the interconnects in first interconnect layer 205 include W, which has a relatively high thermal budget (compatible with high-temperature processes) and good quality (fewer defects, e.g., voids) among conductive metal materials.

As shown in FIG. 2, second semiconductor structure 207 can further include a first bonding layer 206 at bonding interface 209 and above and in contact with first interconnect layer 205. First bonding layer 206 can include a plurality of bonding contacts 233. Bonding contacts 233 can include conductive materials including, but not limited to, W, Co, Cu, Al, silicides, or any combination thereof. In some implementations, bonding contacts 233 of first bonding layer 206 include Cu. The remaining area of first bonding layer 206 can be formed with dielectrics including, but not limited to, silicon oxide, silicon nitride, silicon oxynitride, low-k dielectrics, or any combination thereof. Bonding contacts 233 and surrounding dielectrics in first bonding layer 206 can be used for hybrid bonding (also known as “metal/dielectric hybrid bonding”), which is a direct bonding technology (e.g., forming bonding between surfaces without using intermediate layers, such as solder or adhesives) and can obtain metal-metal (e.g., Cu-to-Cu) bonding and dielectric-dielectric (e.g., SiO₂-to-SiO₂) bonding simultaneously. For example, bonding interface may be distinguished based on the relative positions, e.g., shifts, of bonded contacts 231 and 233.

As shown in FIG. 2, first semiconductor structure 203 can include a second bonding layer 208 at bonding interface 209, e.g., on the opposite side of bonding interface 209 with respect to first bonding layer 206 in second semiconductor structure 207. Second bonding layer 208 can include a plurality of bonding contacts 231 and dielectrics electrically isolating bonding contacts 231. Bonding contacts 231 can include conductive materials, such as Cu. The remaining area of second bonding layer 208 can be formed with dielectric materials, such as silicon oxide. Bonding contacts 231 and surrounding dielectrics in second bonding layer 208 can be used for hybrid bonding. In some implementations, bonding interface 209 is the place at which second bonding layer 208 and first bonding layer 206 are met and bonded. In practice, bonding interface 209 can be a layer with a certain thickness that includes the top surface of first bonding layer 206 and the bottom surface of second bonding layer 208.

As shown in FIG. 2, first semiconductor structure 203 can further include a second interconnect layer 210 above and in contact with second bonding layer 208 to transfer electrical signals. Second interconnect layer 210 can include a plurality of interconnects, such as MEOL interconnects and BEOL interconnects. In some implementations, the interconnects in second interconnect layer 210 also include local interconnects, such as bit line contacts and word line contacts. Second interconnect layer 210 can further include one or more ILD layers in which the lateral lines and vias can form. The interconnects in second interconnect layer 210 can include conductive materials including, but not limited to, W, Co, Cu, Al, silicides, or any combination thereof. The ILD layers in second interconnect layer 210 can include dielectric materials including, but not limited to, silicon oxide, silicon nitride, silicon oxynitride, low-k dielectrics, or any combination thereof.

As shown in FIG. 2, first semiconductor structure 203 can include a memory cell array, such as an array of NAND memory channels 217 above and in contact with second interconnect layer 210. In some implementations, first semiconductor structure 203 can also include one or more dummy channels 250, which may include a first subset of dummy channels 250 in non-array region 110 and a second subset of dummy channels 250 in core region 108. As for the first subset of dummy channels 250 in non-array region 110, one or more dummy channels 250 have a first vertical dimension, while others have a second vertical dimension, and the first vertical dimension is smaller than the second dimension. As for the second subset of dummy channels 250 in core region 108, they also have the second vertical dimension or a vertical dimension similar to the second vertical dimension. In some implementations, second interconnect layer 210 is vertically between NAND memory channels 217 and bonding interface 209. Each NAND memory channel 217 extends vertically through a plurality of pairs of gate conductive layer 239 and dielectric layer 240, according to some implementations. The stacked and interleaved gate conductive layers 239 and dielectric layers 240 are also referred to herein as a stack structure, e.g., a memory stack 212 (conductive/dielectric layer pairs). The interleaved gate conductive layers 239 and dielectric layers 240 in memory stack 212 alternate in the vertical direction, according to some implementations. Each gate conductive layer 239 can include a gate electrode (gate line) surrounded by an adhesive layer and a gate dielectric layer. The adhesive layer can include conductive materials, such as titanium nitride (TiN), which can improve the adhesiveness between the gate electrode and the gate dielectric layer. The gate electrode of gate conductive layer 239 can extend laterally as a word line, ending at one or more staircase structures of memory stack 212. The staircase structures, located in staircase region, which is part of non-array region 110, may be in contact with a plurality of word line contacts 237 for applying voltages on gate conductive layers 239.

The number of the pairs of gate conductive layers 239 and dielectric layers 240 in memory stack 212 can be one of the factors that determine the number of memory cells in the memory cell array. Gate conductive layer 239 can include conductive materials including, but not limited to, tungsten (W), cobalt (Co), copper (Cu), aluminum (Al), polysilicon, doped silicon, silicides, or any combination thereof. In some implementations, each gate conductive layer 239 includes a metal layer, such as a tungsten layer. In some implementations, each gate conductive layer 239 includes a doped polysilicon layer. Each gate conductive layer 239 can include control gates surrounding the memory cells.

As shown in FIG. 2, each NAND memory channel 217 includes a channel structure extending vertically through memory stack 212. In some implementations, the channel structure includes a channel hole filled with semiconductor material(s) (e.g., as a semiconductor channel) and dielectric material(s) (e.g., as a memory film). In some implementations, the semiconductor channel includes silicon, such as polysilicon. In some implementations, the memory film is a composite dielectric layer including a tunneling layer, a storage layer (also known as a “charge trap/storage layer”), and a blocking layer. The channel structure can have a cylinder shape (e.g., a pillar shape). The semiconductor channel, the tunneling layer, the storage layer, the blocking layer are arranged radially from the center toward the outer surface of the pillar in this order, according to some implementations. The tunneling layer can include silicon oxide, silicon oxynitride, or any combination thereof. The storage layer can include silicon nitride, silicon oxynitride, silicon, or any combination thereof. The blocking layer can include silicon oxide, silicon oxynitride, high dielectric constant (high-k) dielectrics, or any combination thereof. In one example, the memory film may include a composite layer of silicon oxide/silicon oxynitride/silicon oxide (ONO). The channel structure can further include a channel plug on the drain end of NAND memory channel 217. The channel plug can include polysilicon and be in contact with the semiconductor channel. In some implementations, each NAND memory channel 217 is a “charge trap” type of NAND memory. It is understood that NAND memory channels 217 are not limited to the “charge trap” type of NAND memory channels and may be “floating gate” type of NAND memory channels in other examples.

3D memory device 200 may include one or more substrate layers 211 above and in contact with memory stack 212. At least one substrate layer 211 can be in contact with the sidewall of the semiconductor channel of the channel structure at the source end of each NAND memory channels 217. Substrate layers 211 can include materials including but not limited to polysilicon, doped polysilicon, crystallized silicon, or doped amorphous silicon. In some implementations, after depositing the doped amorphous silicon to form the substrate layers 211, a portion of the doped amorphous silicon layer in the core region is converted to a conductive polysilicon layer by performing a local thermal treatment. In some implementations, at least one substrate layer 211 is doped with N-type dopants such as phosphorus and/or arsenic. The thickness of substrate layers 211 may be in a range of 100 nm to 600 nm.

Substrate layers 211 include a first segment 211-1 in the non-array region, and second segment 211-3 in the core region. First segment 211-1 of substrate layer 211 is separated by an insulating structure 213 into two portions, including first portion 211-1-1 that is close to the core region and second portion 211-1-2 that is away from the core region. In some implementations, insulating structure 213 may include a first portion 213-1 extending along a lateral direction from the non-array region 110 to the core region 108 and a second portion 213-2 extending along a vertical direction through the substrate layers 211 in the non-array region (i.e., first segment 211-1), and the second portion 213-2 of insulating structure 213 surrounds the core region 108. In some implementations, second portion 213-2 extends through the substrate layers 211 that is located between multiple core regions. In some implementations, second portion 213-2 of insulating structure 213 divides the first segment 211-1 of substrate layers 211 in the non-array region into two portions (i.e., first portion 211-1-1 and second portion 211-1-2), and second portion 213-2 of insulating structure 213 has a critical dimension no less than 10 μm between the two portions of the substrate layer 211, and the critical dimension is a minimum lateral distance between an edge of the second portion 213-2 of insulating structure 213 close to the core region and an edge of the second portion 213-2 of insulating structure 213 away from the core region. In some implementations, second portion 213-2 of insulating structure 213 is in contact with one or more dummy channels 250. In some implementations, substrate layers 211 include second segment 211-3. The second segment of substrate layer 211-3 may be obtained by converting the portion of substrate layer 211 in the core region using a suitable process, such as localized annealing. Insulating structure 213 may laterally be in contact with each of first and second portions of 211-1-1 and 211-1-2 of substrate layers 211-1, and may have the same thickness as substrate layers 211. First and second portions 211-1-1 and 211-1-2 of substrate layer 211-1 may be disconnected/insulated from each other by insulating structure 213. In some implementations, insulating structure 213 is a single insulating layer that includes consistent medium/material in the x-y plane. That is, insulating structure 213 may not be disconnected between any two contact structures 215. Second segment 211-3 of substrate layers 211, located in core region 108, may be in contact with the source ends of NAND memory channels 217. An area of second segment 211-3 of substrate layer 211 may be sufficiently large, e.g., larger than or equal to the total area (e.g., a sub-region of core region 108) in which all NAND memory channels 217 are formed, to be in contact with the source ends of all NAND memory channels 217. The orthographic projection of insulating structure 213 in the x-y plane may cover a plurality, e.g., all, contact structure 215. In various implementations, the orthographic projection of insulating structure 213 is at least partially overlapped with the staircase region. In some implementations, the orthographic projection of insulating structure 213 has no overlap with core region 108. Second portions 211-1-2 of substrate layers 211-1 may or may not exist in various implementations. In some implementations, a top surface of insulating structure 213 is coplanar with a top surface of substrate layers 211, and a bottom surface of insulating structure 213 is coplanar with a bottom surface of substrate layers 211. Insulating structure 213 may include a dielectric material such as silicon oxide, silicon nitride, and/or silicon oxynitride. In some implementations, insulating structure 213 includes silicon oxide.

As shown in FIG. 2, first semiconductor structure 203 can further include one or more contact structures 215 extending vertically in, e.g., through second portion 213-2 of insulating structure 213. In some implementations, contact structures 215 penetrate through the second portion 213-2 of the insulating structure 213, and contact structures 215 are electrically insulated from the substrate layers 211 by the insulating structure 213. In some implementations, each contact structure 215 has a maximum first dimension D1 along a first direction (e.g., x-direction) and has a minimum distance D2 from substrate layers 211, and the maximum first dimension D1 is smaller than the minimum distance D2. In some implementations, contact structures 215 couples the interconnects in second interconnect layer 210 to second contact structures 219 in a pad-out interconnect layer to facilitate electrical connection through first semiconductor structure 203. Contact structures 215 can include conductive materials including, but not limited to, W, Co, Cu, Al, silicides, or any combination thereof. In some implementations, contact structures 215 include W. In some implementations, contact structures 215 each may be a TSV having a depth, e.g., length along the z-direction, in the micron- or tens micron-level (e.g., between 1 μm and 100 μm).

As shown in FIG. 2, contact structures 215 may be located in non-array region 110 of first semiconductor structure 203 or may be located away, e.g., in the x-y plane, from NAND memory channels 217. In some implementations, insulating structure 213 may be partially or fully located in non-array region 110 to provide insulation of at least one contact structure 215 from substrate layers 211. In some implementations, insulating structure 213 is located in the staircase structure of 3D memory device 200. In some other implementations, insulating structure 213 is located outside the staircase structure but in non-array region 110. In some implementations, a width of second portion 213-2 of insulating structure 213 in the x-direction and/or y-direction is sufficiently large to enclose a plurality of, e.g., all, contact structures 215 in non-array region 110 such that all contact structures 215 surrounded/in second portion 213-2 of insulating structure 213 are insulated from first segment 211-1 of substrate layers 211. Insulating structure 213 may also insulate second portions of substrate layers 211-2, if any, from first portion of substrate layers 211-1. In various implementations, insulating structure 213 may be away from the source ends of NAND memory channels 217, and the width and/or area of insulating structure 213 can be desirably large to insulate a maximum number of contact structures 215. For example, an area (e.g., a sub-region of non-array region 110) of insulating structure 213 may be greater than or equal to the total area in which contact structures 215 are located. In some implementations, insulating structure 213 is located in non-array region 110.

In some implementations, second contact structures 219 are formed on top of substrate layers 211 (e.g., second segment 211-3 of substrate layers 211) and are conductively connected to contact structures 215 to drive the transistors in the peripheral circuit in device layer 204. In some implementations, second contact structures 219 conductively connected to NAND memory channels 217 are employed to provide voltages for operations of the memory cells such as erase, write, and read.

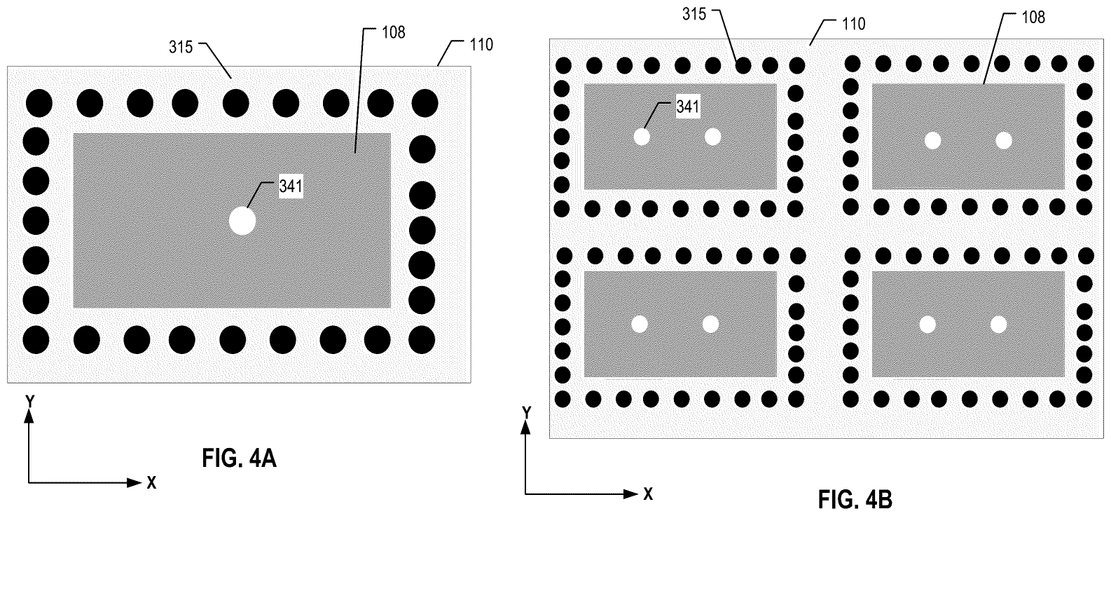

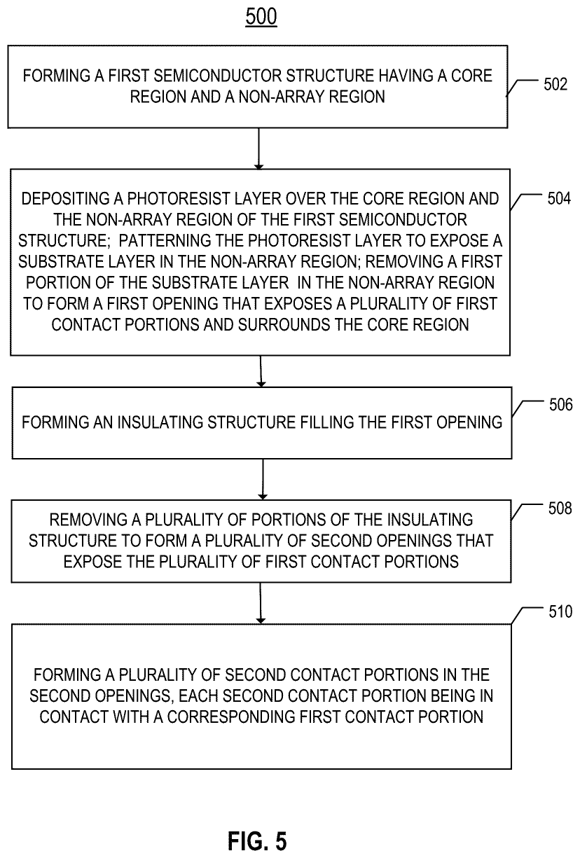

FIGS. 3A-3F illustrate a fabrication process for forming 3D memory device 200, according to some aspects of the present disclosure. FIG. 4 illustrates an example of a plan view for forming the 3D memory devices in FIG. 2, according to some aspects of the present disclosure. FIG. 5 illustrates a flowchart of a method 500 for forming 3D memory devices 200, according to some aspects of the present disclosure. It is understood that the operations shown in method 500 are not exhaustive and that other operations can be performed as well before, after, or between any of the illustrated operations. Further, some of the operations may be performed simultaneously, or in a different order than shown in FIG. 5.

Referring to FIG. 5, method 500 starts at operation 502, forming a first semiconductor structure having a core region and a non-array region. FIG. 3A illustrates a corresponding structure.

As shown in FIG. 3A, a first semiconductor structure 303 is formed, which has a core region 108 and a non-array region 110. In some implementations, the first semiconductor structure 303 may be bonded with a second semiconductor structure 307, and together they form semiconductor structure 350. Semiconductor structure 350 may be an example of 3D memory device 200. As shown in FIG. 3A, semiconductor structure 350 may include the first semiconductor structure 303 bonded with the second semiconductor structure 307 at a bonding interface 309. The second semiconductor structure 307 may include a substrate 302, a device layer 304, an interconnect layer 305, and a first bonding layer 306. The first semiconductor structure 303 may include a second bonding layer 308, an interconnect layer 310, and an array stack 312. Array stack 312 may include interleaved a plurality of gate conductive layers 339 and a plurality of dielectric layers 340. Array stack 312 may also include an array of NAND memory channels 317 extending in the interleaved gate conductive layers 339 and dielectric layers 340. The first semiconductor structure may also include one or more first contact portions 315-1 extending vertically and coupled to interconnect layer 310. First contact portion 315-1 may subsequently form a lower part of a TSV (e.g., contact structure 215). NAND memory channels 317 may be located in core region 108, and first contact portion 315-1 may be located in non-array region 110. The detailed description of each component may be referred the description of 3D memory device 200 in FIG. 2, and is not repeated herein.

To form the first semiconductor structure 303, a stack structure, such as a memory stack including interleaved gate conductive layers and dielectric layers, is formed on a first substrate 311 to form array stack 312. In some implementations, the first substrate 311 includes a suitable base material such as silicon, polysilicon, doped polysilicon, amorphous silicon, or amorphous doped silicon. The first substrate 311 may be made from amorphous silicon or amorphous doped silicon, and it may be locally annealed in the core region 108 such that the amorphous silicon or amorphous doped silicon converts into conductive polysilicon or doped polysilicon. After localized annealing, two segments of the substrate may be formed from the first substrate 311: first segment 311-1 in the non-array region 110 remaining amorphous silicon or amorphous doped silicon and second segment 311-3 in the core region transformed to polysilicon or doped polysilicon.

To form the memory stack, in some implementations, a dielectric stack (not shown) including interleaved sacrificial layers (not shown) and the dielectric layers is formed on the first substrate 311. In some implementations, each sacrificial layer includes a layer of silicon nitride, and each dielectric layer includes a layer of silicon oxide. The interleaved sacrificial layers and dielectric layers can be formed by one or more thin film deposition processes including, but not limited to, chemical vapor deposition (CVD), physical vapor deposition (PVD), atomic layer deposition (ALD), or any combination thereof. The dielectric stack may be repeatedly patterned to form a plurality of stairs in non-array region 110. The memory stack can then be formed by a gate replacement process, e.g., replacing the sacrificial layers with the conductive layers using wet/dry etch of the sacrificial layers selective to the dielectric layers and filling the resulting recesses with the conductive layers. In some implementations, each conductive layer includes a metal layer, such as a layer of W. It is understood that the memory stack may also be formed by alternatingly depositing conductive layers (e.g., doped polysilicon layers) and dielectric layers (e.g., silicon oxide layers) without the gate replacement process, in some examples. In some implementations, a pad oxide layer (e.g., thermally grown local oxidation of silicon (LOCOS)), including silicon oxide, is formed between the memory stack and the first substrate. A plurality of contact vias may be formed extending vertically and landed on the stairs to form electrical connections between gate conductive layers 339 and interconnect layer 310 that is to be formed.

NAND memory channels 317 may be formed above the first substrate 311. Each NAND memory channel 317 extends vertically through the dielectric stack (or the memory stack, depending on the fabrication process) to be in contact with the first substrate. In some implementations, the fabrication processes to form NAND memory channels 317 include forming a channel hole through the dielectric stack (or the memory stack) and into the first substrate using dry etching/and or wet etching, such as deep reactive-ion etching (DRIE), followed by subsequently filling the channel hole with a plurality of layers, such as a memory film (e.g., a tunneling layer, a storage layer, and a blocking layer) and a semiconductor layer, using thin film deposition processes such as ALD, CVD, PVD, or any combination thereof.

In some implementations, interconnect layer 310 is formed above the array of NAND memory channels 317 on the first substrate. Interconnect layer 310 can include a first plurality of interconnects in one or more ILD layers. Interconnect layer 310 can include interconnects of MEOL and/or BEOL in a plurality of ILD layers to make electrical connections with NAND memory channels 317. In some implementations, interconnect layer 310 includes multiple ILD layers and interconnects therein formed in multiple processes. For example, the interconnects in interconnect layer 310 can include conductive materials deposited by one or more thin film deposition processes including, but not limited to, CVD, PVD, ALD, electroplating, electroless plating, or any combination thereof. Fabrication processes to form interconnects can also include photolithography, chemical mechanical polishing (CMP), wet/dry etch, or any other suitable processes. The ILD layers can include dielectric materials deposited by one or more thin film deposition processes including, but not limited to, CVD, PVD, ALD, or any combination thereof. The ILD layers and interconnects illustrated can be collectively referred to as interconnect layer 310. In some implementations, the interconnects in interconnect layer 310 include W, which has a relatively high thermal budget among conductive metal materials to sustain later high-temperature processes.

In some implementations, second bonding layer 308 is formed above interconnect layer 310. Second bonding layer 308 can include a plurality of first bonding contacts 331 surrounded by dielectrics. In some implementations, a dielectric layer is deposited on the top surface of interconnect layer 310 by one or more thin film deposition processes including, but not limited to, CVD, PVD, ALD, or any combination thereof. First bonding contacts 331 can then be formed through the dielectric layer and in contact with the interconnects in interconnect layer 310 by first patterning contact holes through the dielectric layer using a patterning process (e.g., photolithography and dry/wet etch of dielectric materials in the dielectric layer). The contact holes can be filled with a conductor (e.g., Cu). In some implementations, filling the contact holes includes depositing an adhesion (glue) layer, a barrier layer, and/or a seed layer before depositing the conductor.

To form the second semiconductor structure 307, device layer 304 is formed on substrate 302 (e.g., a second substrate). Device layer 304 may include a plurality of transistors on substrate 302. Substrate 302 can be a silicon substrate having single crystalline silicon. The transistors can be formed by a plurality of processes including, but not limited to, photolithography, dry/wet etch, thin film deposition, thermal growth, implantation, CMP, and any other suitable processes. In some implementations, doped regions are formed in substrate 302 by ion implantation and/or thermal diffusion, which function, for example, as wells and source/drain regions of the transistors. In some implementations, isolation regions (e.g., shallow trench isolation (STIs)) are also formed in substrate 302 by wet/dry etch and thin film deposition. The transistors may function as part or all of the peripheral circuits for controlling NAND memory channels 317. It is understood that the details of fabricating transistors may vary depending on the types of the transistors and thus, are not elaborated for ease of description.

In some implementations, interconnect layer 305 is formed above the transistor on substrate 302. Interconnect layer 305 can include a plurality of interconnects in one or more ILD layers. As illustrated in FIG. 3A, interconnect layer 305 can be formed above the transistors in device layer 304. Interconnect layer 305 can include interconnects of MEOL and/or BEOL in a plurality of ILD layers to make electrical connections with the transistors. In some implementations, interconnect layer 305 includes multiple ILD layers and interconnects therein formed in multiple processes. In some implementations, first contact portions 315-1 may be formed, in non-array region 110, extending in array stack 312 and coupled to interconnects in interconnect layer 305. The formation of first contact portions 315-1 may include photolithography, etching, and deposition. For example, first contact portions 315-1 and the interconnects in interconnect layer 305 can include conductive materials deposited by one or more thin film deposition processes including, but not limited to, CVD, PVD, ALD, electroplating, electroless plating, or any combination thereof. Fabrication processes to form interconnects can also include photolithography, CMP, wet/dry etch, or any other suitable processes. The ILD layers can include dielectric materials deposited by one or more thin film deposition processes including, but not limited to, CVD, PVD, ALD, or any combination thereof. The ILD layers and interconnects can be collectively referred to as interconnect layer 305. In some implementations, the interconnects in interconnect layer 305 include W, which has a relatively high thermal budget among conductive metal materials to sustain later high-temperature processes.

In some implementations, first bonding layer 306 is formed above interconnect layer 305. First bonding layer 306 can include a plurality of second bonding contacts 333 surrounded by dielectrics. In some implementations, a dielectric layer is deposited on the top surface of interconnect layer 305 by one or more thin film deposition processes including, but not limited to, CVD, PVD, ALD, or any combination thereof. Second bonding contacts 333 can then be formed through the dielectric layer and in contact with the interconnects in interconnect layer 305 by first patterning contact holes through the dielectric layer using a patterning process (e.g., photolithography and dry/wet etch of dielectric materials in the dielectric layer). The contact holes can be filled with a conductor (e.g., Cu). In some implementations, filling the contact holes includes depositing an adhesion (glue) layer, a barrier layer, and/or a seed layer before depositing the conductor.

As illustrated in FIG. 3A, the first semiconductor structure 303 (e.g., array stack 312 and NAND memory channels 317 formed therethrough) are flipped upside down. Second bonding layer 308 facing down is bonded with first bonding layer 306 facing up, i.e., in a face-to-face manner, thereby forming bonding interface 309. That is, the first and second bonding contacts in bonding layers 308 and 306 are bonded at bonding interface 309. In some implementations, a treatment process, e.g., plasma treatment, wet treatment and/or local thermal treatment, is applied to bonding surfaces prior to bonding. As a result of the bonding, e.g., hybrid bonding, the first and second bonding contacts 331 and 333 on opposite sides of bonding interface 309 can be inter-mixed. After the bonding, first bonding contacts 331 in second bonding layer 308 and second bonding contacts 333 in first bonding layer 306 are aligned and in contact with one another, such that array stack 312 and NAND memory channel 317 formed therethrough can be coupled to the transistors through the bonded bonding contacts across bonding interface 309, according to some implementations. The first substrate may then be partially or fully removed to expose the source ends of NAND memory channels 317. In some implementations, the removal of the first substrate includes a suitable etching process (e.g., dry etch and/or wet etch) and/or a planarization process (e.g., chemical mechanical polishing or CMP). The bonded chip, with the first substrate partially or fully removed, may be referred to as semiconductor structure 350.

Method 500 proceeds to operation 504, in which a first photoresist layer is deposited over the core region and the non-array region of the first semiconductor structure, a portion of the first photoresist layer 320 and a portion of first substrate 311 are then removed in the non-array region to form a first opening. The first opening exposes a plurality of first contact structures and surrounds the core region. FIG. 3A and FIG. 3B illustrate corresponding structures.

First photoresist layer 320 may be deposited over first substrate 311 of semiconductor structure 350. In some implementations, first photoresist layer 320 is etched through a patterned mask that defines a desired pattern, exposing the first substrate 311. The exposed areas of first substrate 311 are selectively removed, resulting in forming first opening 322 that exposes a plurality of first contact portions 315-1 and surrounds the core range as shown in FIG. 3B. First photoresist layer 320 may then be removed, e.g., using an ashing process. The forming of first opening 322 may divide first segment 311-1 of first substrate in the non-array region 110 into two portions: first portion 311-1-1 that is close to the core region and second portion 311-1-2 that is away from the core region. In some implementations, the forming the first opening 322 leads to removing an upper portion of a dummy channel 355, such that the vertical dimension of dummy channel 355 is shortened and is less than that of a NAND memory channel 317. In some implementations, the critical dimension (CD) of first opening 322, which is the minimum lateral distance between an edge of the first opening close to the core region and an edge of the first opening away from the core region, is sufficiently large, such that all the first substrate 311 in the non-array region that is not used for conducting electricity is partially or completely removed. In one implementation not shown in the figures, first segment 311-1 can be completely removed, while keeping second segment 311-3 of first substrate 311 in the core region. In another implementation not shown in the figures, second portion 311-1-2 of first substrate 311 can be completed removed, while keeping first portion 311-1-1 of first substrate 311 in the non-array region and second segment 311-3 of first substrate 311 in the core region. In some implementations, the CD of first opening 322 is larger than 10 μm. In some implementations, an aspect ratio (e.g., a ratio of depth over width) of first opening 322 is less than or equal to ⅓. For example, the aspect ratio is less than or equal to ⅕. The small aspect ratio can allow the deposition process of insulating material into first opening 322 to be cheaper and easier. In some implementations, no ALD is needed for the deposition. In some implementations, first opening 322 is a single opening.

Referring back to FIG. 5, method 500 proceeds to operation 506, in which an insulating material is deposited over the first substrate and in the first opening, forming an insulating structure filling the first opening and an insulating layer that is above the insulating structure and covers the first semiconductor structure 303. FIG. 3C illustrates a corresponding structure.

As shown in FIG. 3C, an insulating material may be deposited over first substrate 311 and in first opening 322, forming an insulating structure 323 in first opening 322 and an insulating layer 324 over insulating structure 323 and first substrate 311. Insulating structure 323 may be formed by filling first opening 322 with the insulating material and may cover any first contact portions 315-1 exposed in first opening 322. Insulating structure 323 may be in contact with first portion 311-1-1 of first substrate 311 and second portion 311-1-2 of first substrate 311 (if any). In some implementations, if first substrate 311 does not include second portion 311-1-2, insulating layer 324 may laterally extend to an outer periphery of non-array region 110. The insulating material, such as a dielectric material, may include silicon oxide, silicon nitride, silicon oxynitride, and/or other low-k dielectrics. The insulating material may be deposited using any suitable deposition method, such as CVD, PVD, and/or ALD. In some implementations, the deposition of the insulating material does not include ALD. In some implementations, a planarization process, such as chemical mechanical polishing (CMP) is used to flatten insulating layer 324.

Referring to FIG. 5, method 500 proceeds to operation 508, in which a plurality of second openings are formed through the insulating structure and the insulating layer in the non-array region, and one or more third openings are formed in the insulating layer in the core region. FIGS. 3D and 3E illustrate corresponding structures.

As shown in FIG. 3D, a second photoresist layer 352 may be formed over insulating layer 324 in core region 108 and non-array region 110. The second photoresist layer 352 may be patterned to include opening 354 for forming contact portions connecting first contact portions 315-1, and one or more openings 356 (in core region 108) for forming contact portions connecting second segment 311-3 of first substrate 311 and pad-out interconnects. Openings 354 and 356 may each expose insulating layer 324. In some implementations, opening 354 may be aligned with a respective first contact portions 315-1 in the z-direction.

As shown in FIG. 3E, a suitable etching process, e.g., dry etch and/or wet etch, may be performed, using patterned second photoresist layer 352 as the etch mask, to form a plurality of second opening 360 through insulating layer 324. The plurality of second openings 360 surround the core region, and each second opening 360 exposes a respective first contact portion 315-1. In some implementations, because insulating layer 324 and insulating structure 323 may be composed of the same material, in a same etching process, during forming the plurality of second openings 360, one or more third openings 358 are formed in insulating layer 324 over the core region and expose the second segment 311-3 of first substrate 311. Patterned second photoresist layer 352 may then be removed, e.g., using an ashing process.

Referring back to FIG. 5, method 500 proceeds to operation 510, in which a second contact portion is formed in each second opening, and a third contact portion is formed in each third opening. Each second contact portion is in contact with a corresponding first contact portion. Each second contact portion has a lateral width that is less than a lateral distance between the second contact portion and the substrate layer. FIG. 3F illustrates a cross-section view of a corresponding structure, and FIG. 4A illustrates a plan view of a corresponding structure.

As shown in FIG. 3F, a second contact portion 315-2 is formed in each second opening 360, and a second contact structure 341 is formed in each third opening 358. Second contact portion 315-2 may each be in contact with the respective first contact portion 315-1. In some implementations, each second contact portion 315-2 has a minimum lateral width D3 that is less than a minimum lateral distance D4 between the second contact portion 315-2 and the first substrate 311. In some implementations, each first contact portion 315-1 and the respective second contact portion 315-2 may form a first contact structure 315, e.g., a TSC. As shown in FIG. 4A, first contact structures 315 are formed in non-array region 110 and surround core region 108. In some implementations, core region 108 has one or more second contact structures 341. In some implementations, there are multiple (e.g., two or more) core regions 108 each having one or more second contact structures 341, and the multiple core regions 108 have non-array regions 110 located therebetween, each non-array region 110 has a plurality of first contact structures 315 as shown in one example illustrated by FIG. 4B. Second contact portions 315-2 and second contact structure 341 may each include tungsten (W), cobalt (Co), copper (Cu), aluminum (Al), polysilicon, doped silicon, silicides, or any combination thereof. In some implementations, second contact portions 315-2 and second contact structure 341 may be formed by depositing a layer of conductive material to fill second and third openings 360 and 358, and perform a recess etch (e.g., a blank etch) to remove any excess conductive material on insulating layer 324. In some implementations, the deposition of the conductive material includes CVD, PVD, ALD, electroplating, electroless plating, or a combination thereof. The recess etch may include a suitable dry etch and/or wet etch.

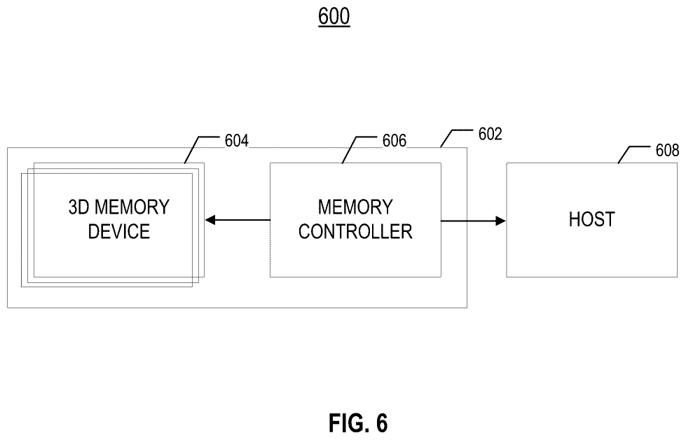

FIG. 6 illustrates a block diagram of a system 600 having a memory device, according to some aspects of the present disclosure. System 600 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 6, system 600 can include a host 608 and a memory system 602 having one or more memory devices 604 and a memory controller 606. Host 608 can be a processor of an electronic device, such as a central processing unit (CPU), or a system-on-chip (SoC), such as an application processor (AP). Host 608 can be configured to send or receive the data to or from memory devices 604.

Memory device 604 can be any memory devices disclosed herein, such as 3D memory device 200. In some implementations, each memory device 604 includes an array of memory cells, a peripheral circuit of the array of memory cells. The array of memory cells and the peripheral circuit are stacked over one another in different planes, as described above in detail.

Memory controller 606 is coupled to memory device 604 and host 608 and is configured to control memory device 604, according to some implementations. Memory controller 606 can manage the data stored in memory device 604 and communicate with host 608. In some implementations, memory controller 606 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 606 is designed for operating in a high duty-cycle environment SSDs or embedded multi-media-cards (eMMCs) used as data storage for mobile devices, such as smartphones, tablets, laptop computers, etc., and enterprise storage arrays. Memory controller 606 can be configured to control operations of memory device 604, such as read, erase, and program operations. In some implementations, memory controller 606 is configured to control the array of memory cells through the first peripheral circuit and the second peripheral circuit. Memory controller 606 can also be configured to manage various functions with respect to the data stored or to be stored in memory device 604 including, but not limited to bad-block management, garbage collection, logical-to-physical address conversion, wear leveling, etc. In some implementations, memory controller 606 is further configured to process error correction codes (ECCs) with respect to the data read from or written to memory device 604. Any other suitable functions may be performed by memory controller 606 as well, for example, formatting memory device 604. Memory controller 606 can communicate with an external device (e.g., host 608) according to a particular communication protocol. For example, memory controller 606 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

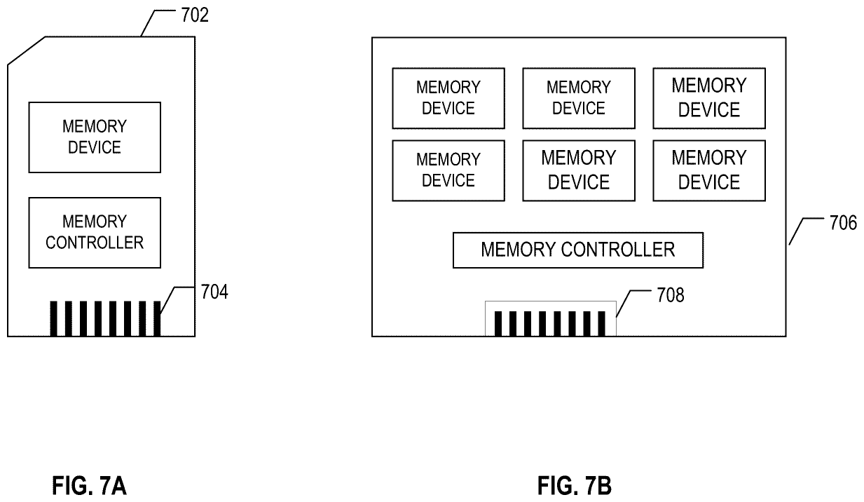

Memory controller 606 and one or more memory devices 604 can be integrated into various types of storage devices, for example, be included in the same package, such as a universal Flash storage (UFS) package or an eMMC package. That is, memory system 602 can be implemented and packaged into different types of end electronic products. In one example as shown in FIG. 7A, memory controller 606 and a single memory device 604 may be integrated into a memory card 702. Memory card 702 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 702 can further include a memory card connector 704 coupling memory card 702 with a host (e.g., host 608 in FIG. 6). In another example as shown in FIG. 7B, memory controller 606 and multiple memory devices 604 may be integrated into an SSD 706. SSD 706 can further include an SSD connector 708 coupling SSD 706 with a host (e.g., host 608 in FIG. 6). In some implementations, the storage capacity and/or the operation speed of SSD 706 is greater than those of memory card 702.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A three-dimensional (3D) memory device, comprising:
a first semiconductor structure having a core region and a non-array region, the first semiconductor structure comprising:
an array of channel structures in the core region;
a substrate layer extending from the non-array region to the core region and being in contact with the array of channel structures;
an insulating structure, comprising a first portion extending along a lateral direction from the non-array region to the core region and a second portion extending along a vertical direction through the substrate layer in the non-array region, wherein the second portion of the insulating structure surrounds the core region; and
contact structures penetrating through the second portion of the insulating structure, wherein the contact structures are electrically insulated from the substrate layer by the insulating structure.

2. The 3D memory device of claim 1, wherein the insulating structure insulates the contact structures from one another, and a minimum lateral width of the contact structures is less than a minimum lateral distance between the contact structures and the substrate layer.

3. The 3D memory device of claim 2, wherein the second portion of the insulating structure divides the substrate layer in the non-array region into two parts, and the second portion of the insulating structure has a critical dimension no less than 10 μm, wherein the critical dimension is a minimum lateral distance between an edge of the second portion of the insulating structure close to the core region and an edge of the second portion of the insulating structure away from the core region.

4. The 3D memory device of claim 2, wherein at least one first contact structure is located in the non-array region, and at least one second contact structure is located in the core region, wherein the at least one first contact structure in the non-array region extends vertically through the substrate layer, and the at least one first contact structure is electrically connected to the at least one second contact structure.

5. The 3D memory device of claim 1, wherein the insulating structure comprises at least one of silicon oxide, silicon nitride, or silicon oxynitride.

6. The 3D memory device of claim 1, wherein the second portion of the insulating structure is in contact with a dummy channel.

7. The 3D memory device of claim 6, wherein the dummy channel has a vertical dimension less than that of the channel structures.

8. The 3D memory device of claim 1, wherein the second portion of the insulating structure extends vertically in the non-array region, and the non-array region is located between multiple core regions.

9. The 3D memory device of claim 1, wherein the first semiconductor structure further comprises a bonding interface, and the first semiconductor structure connects with a second semiconductor structure through the bonding interface.

10. A system, comprising a memory device and a memory controller,
wherein the memory device is configured to store data, comprising:
a first semiconductor structure having a core region and a non-array region, the first semiconductor structure comprising:
an array of channel structures in the core region;
a substrate layer extending from the non-array region to the core region and being in contact with the array of channel structures;
an insulating structure, comprising a first portion extending along a lateral direction from the non-array region to the core region and a second portion extending along a vertical direction through the substrate layer in the non-array region, wherein the second portion of the insulating structure surrounds the core region; and
contact structures penetrating through the second portion of the insulating structure, wherein the contact structures are electrically insulated from the substrate layer by the insulating structure, and a minimum lateral width of the contact structures is less than a minimum lateral distance between the contact structures and the substrate layer, and
a second semiconductor structure bonded with the first semiconductor structure, the second semiconductor structure comprising a transistor,
wherein the memory controller is coupled to the memory device and configured to control the memory device.

11. A method for forming a three-dimensional (3D) memory device, comprising:
forming a first semiconductor structure comprising a core region and a non-array region;
depositing a photoresist layer over the core region and the non-array region of the first semiconductor structure;
patterning the photoresist layer to expose a substrate layer in the non-array region;
removing a first portion of the substrate layer to form a first opening, wherein the first opening exposes a plurality of first contact portions and surrounds the core region;
forming an insulating structure filling the first opening;
removing a plurality of portions of the insulating structure to form a plurality of second openings, each second opening exposing a corresponding first contact portion; and
forming a plurality of second contact portions in the plurality of second openings, each second contact portion being in contact with the corresponding first contact portion, wherein the plurality of first contact portions and the plurality of second contact portions together form a plurality of first contact structures.

12. The method of claim 11, wherein forming the plurality of second contact portions comprises forming each second contact portion having a minimum lateral width less than a minimum lateral distance between the second contact portion and the substrate layer.

13. The method of claim 11, wherein forming the plurality of second openings of the insulating structure comprises forming the plurality of second openings in the non-array region, wherein the non-array region is located between multiple core regions.

14. The method of claim 11, further comprising:
after forming the insulating structure filling the first opening, planarizing the insulating structure using chemical mechanical polishing.

15. The method of claim 11, wherein removing the first portion of the substrate layer in the non-array region comprises:
forming the first opening with a critical dimension of no less than 10 μm, wherein the critical dimension is a minimum lateral distance between an edge of the first opening close to the core region and an edge of the first opening away from the core region.

16. The method of claim 11, wherein removing the first portion of the substrate layer to form the first opening comprises:
removing an upper portion of a dummy channel.

17. The method of claim 11, wherein forming the insulating structure comprises:
forming the insulating structure that fills the first opening and covers the substrate layer both in the non-array region and the core region.

18. The method of claim 17, further comprising:
during forming the plurality of second openings, removing a portion of the insulating structure in the core region to form a third opening that exposes the substrate layer.

19. The method of claim 18, further comprising:
forming a second contact structure in the third opening, the second contact structure being in contact with the substrate layer in the core region.

20. The method of claim 11, further comprising:
bonding the first semiconductor structure with a second semiconductor structure through a bonding interface.
